(19) United States
(12) Patent Application Publication
(10) Pub. No.: US 2013/0264588 A1
(43) Pub. Date: Oct. 10, 2013

(54) COMPACT LED PACKAGE

(71) Applicants: Heng Liu, Sunnyvale, CA (US); Shih-Feng Shao, New Taipei City (TW)

(72) Inventors: Heng Liu, Sunnyvale, CA (US); Shih-Feng Shao, New Taipei City (TW)

(73) Assignee: PHOSTEK, INC., Taipei City (TW)

(21) Appl. No.: 13/442,422

(22) Filed: Apr. 9, 2012

(51) Int. Cl. H01L 33/08; H01L 33/50

(52) U.S. Cl. 257/88; 438/27; 257/100; 257/E33.06

(57) ABSTRACT

A light emitting package includes a base and one or more LED units coupled to the base. The LED unit includes a plurality of vertically stacked epitaxial structures. Each epitaxial structure includes at least a first doped layer, at least a light emitting layer, and at least a second doped layer. At least one luminescent element is spaced a distance from the one or more LED units.

### BACKGROUND

1. Field of the Invention

The present invention relates to a light emitting devices, and more particularly to packaging for multiple light emitting diodes (LEDs).

2. Description of Related Art

Light emitting diode (LED) chips are commonly used in a variety of applications including many commercial light emitting devices. LED chips may be used for illumination. In illumination applications, however, the relatively low light output of an LED chip may be problematic. Additionally, a typical LED chip emits light over a relatively narrow wavelength range, whereas white illumination may be preferred for some applications.

To overcome some of these problems, light emitting packages that use a plurality of LED chips have been used. Using several LED chips in a single package provides higher light output. In addition, if the colors of the LED chips are suitably selected (for example, by selecting red, green, and blue chips, or a similar combination of saturated colors) the light output of the package can approximate white light.

Alternatively, LED chips that emit in the blue, violet, or ultraviolet range have been coated with a suitable phosphor blend to approximate white light. The output may be substantially completely converted light (e.g., about 100% conversion efficiency with the phosphor producing approximately white light) or can be a blend of direct LED chip emission and converted phosphor emission (e.g., blue direct LED chip emission and yellowish converted phosphor emission that blend to approximate white light).

The design of a light emitting package employing a plurality of LED chips, however, presents certain difficulties. The use of multiple LED chips spreads out the area of light emission, which can be problematic in applications in which a small source is desired. The laterally spread-out light emission may be difficult to focus or otherwise manipulate using diffractive or refractive optical elements. If light from LED chips emitting light at different wavelengths are blended to approximate white light, then a large footprint for the light emitting package may also be problematic by reducing the effectiveness of the light blending. Moreover, in some applications it may be desired to produce a larger total light output. A larger package may be needed to produce the larger total light output. The larger package may result in a higher manufacturing or product cost. Thus, there is a need for large LED packages that produce large total light outputs with lower manufacturing and/or product costs.

### SUMMARY

In certain embodiments, a light emitting package includes a base and one or more LED units coupled to the base. The LED unit includes a plurality of vertically stacked epitaxial structures. Each epitaxial structure may include at least a first doped layer, at least a light emitting layer, and at least a second doped layer. At least one luminescent element is spaced a distance from the one or more LED units.

In certain embodiments, a method for forming a light emitting package includes vertically stacking a plurality of epitaxial structures to form an LED unit. Each epitaxial structure may include at least a first doped layer, at least a light emitting layer, and at least a second doped layer. One or more LED units may be coupled to a base to form an LED array. At least one luminescent element may be formed above the LED array. The luminescent element is spaced a distance from the LED array.

In certain embodiments, a light emitting package includes a base and one or more LED units coupled to the base. The LED unit includes a plurality of vertically stacked epitaxial structures. Each epitaxial structure may include at least a first doped layer, at least a light emitting layer, and at least a second doped layer. An encapsulating material encloses the one or more LED units, wherein the LED unit comprises a total light output greater than a total light output from a single epitaxial structure, and wherein the encapsulating material is approximately the same amount as encapsulating material needed for the single epitaxial structure. Furthermore, the encapsulating material directly or indirectly contacts the LED units.

### BRIEF DESCRIPTION OF THE DRAWINGS

Features and advantages of the methods and apparatus of the present invention will be more fully appreciated by reference to the following detailed description of presently preferred but nonetheless illustrative embodiments in accordance with the present invention when taken in conjunction with the accompanying drawings in which:

FIG. 1A-C depict side-view representations of embodiments of an LED chip packaged in a cup with different phosphor distributions.

FIG. 2A-C depict side-view representations of embodiments of an LED chip packaged on a base (e.g., a board or lead frame) with different phosphor distributions.

FIG. 3A depicts a top view of an embodiment of an LED array with a plurality of LED chips located inside an LED package.

FIG. 3B depicts a top view of an embodiment of an LED array, which is larger than LED array depicted in FIG. 3A.

FIG. 4 depicts a side-view representation of an LED array with vertically stacked epitaxial structures.

FIG. 5 depicts a side-view representation of an embodiment of an LED array positioned in an LED package.

FIG. 6 depicts a representation of an embodiment of a sapphire based LED chip.

FIG. 7 depicts a representation of an embodiment of a p-side up LED chip.

FIG. 8 depicts an embodiment of an LED array with LED chips spaced laterally to form an LED array.

While the invention is susceptible to various modifications and alternative forms, specific embodiments thereof are shown by way of example in the drawings and will herein be described in detail. The drawings may not be to scale. It should be understood that the drawings and detailed description thereto are not intended to limit the invention to the particular form disclosed, but to the contrary, the intention is to cover all modifications, equivalents and alternatives falling within the spirit and scope of the present invention as defined by the appended claims.

### DETAILED DESCRIPTION OF EMBODIMENTS

In the context of this patent, the term “coupled” means either a direct connection or an indirect connection (e.g., one or more intervening connections) between one or more objects or components.

A conventional LED (light emitting diode) chip includes only one epitaxial structure. The epitaxial structure has at least a first doped layer, at least a light emitting layer, and at least a second doped layer. LED (light emitting diode) chips may be packaged in a variety of ways. In some embodiments, an LED chip is located in a cup (e.g., the LED chip is packaged in the cup). In some embodiments, an LED chip is coupled or mounted on a board or a lead frame (e.g., the LED chip is packaged on the board or the lead frame). The LED package may include various types of phosphor distribution to provide white light emission from the package. Various types of phosphor distribution include uniform distribution (within the package), conformal distribution (conformal on the LED chip), and remote distribution (remote from the LED chip).

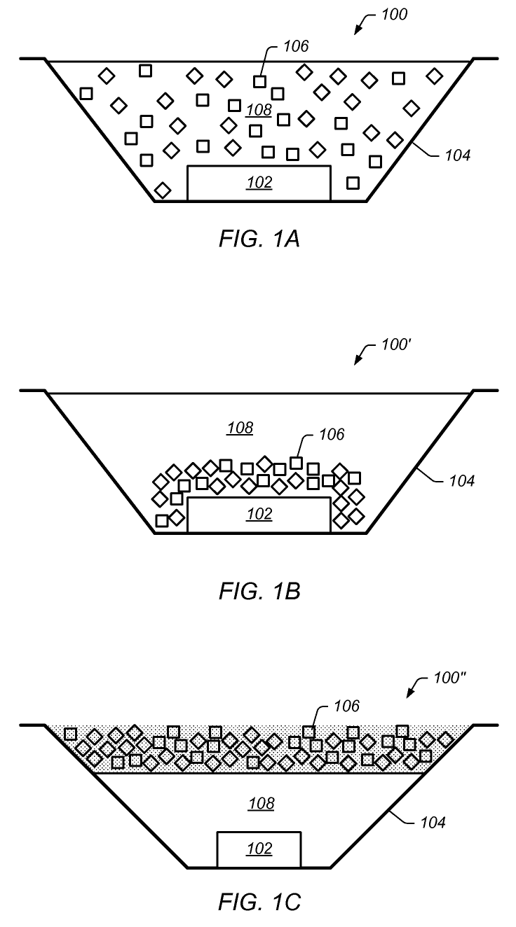

FIGS. 1A-C depict side-view representations of embodiments of an LED chip packaged in a cup with different phosphor distributions. FIG. 1A depicts a side-view representation of an embodiment of LED package 100 with LED chip 102 packaged in cup 104 with uniform distribution of phosphor particles 106. FIG. 1B depicts a side-view representation of an embodiment of LED package 100′ with LED chip 102 packaged in cup 104 with conformal distribution of phosphor particles 106. FIG. 1C depicts a side-view representation of an embodiment of LED package 100″ with LED chip 102 packaged in cup 104 with remote distribution of phosphor particles 106.

Cup 104 may be a base or support for LED chip 102. As shown in FIGS. 1A-C, cup 104 may be a reflector cup (e.g., a specular reflector cup). Cup 104 may increase total light emission from the LED package. In certain embodiments, LED chip 102 is coupled (e.g., bonded) to cup 104 using silver paste. Material 108 may encapsulate LED chip 102 inside cup 104. Material 108 may be, for example, a transparent material with adhesive properties such as, but not limited to, silicone, resin, or epoxy. Material 108 may protect LED chip 102.

In some embodiments, as shown in FIGS. 1A and 1B, phosphor particles 106 are distributed within material 108. As shown in FIG. 1A, phosphor particles 106 are substantially uniformly distributed in material 108 inside cup 104. For example, phosphor particles 106 may be mixed with material 108 to provide a substantially uniform distribution of the particles before encapsulating LED chip 102 in material 108. Phosphor particles 106 and material 108 may form a luminescent element above LED chip 102.

As shown in FIG. 1B, phosphor particles 106 have a conformal distribution around the surface of LED chip 102 and the phosphor particles and the LED chip are enclosed in material 108 inside cup 104. In certain embodiments, phosphor particles 106 are distributed on the surface of LED chip 102 (e.g., positioned on the surface of the LED chip) and then the LED chip and the phosphor particles are encapsulated in material 108. For example, phosphor particles 106 may be coated on LED chip 102 before encapsulation in material 108. Phosphor particles 106 in material 108 may form a luminescent element above LED chip 102.

As shown in FIG. 1C, LED chip 102 is encapsulated in material 108 and then phosphor particles 106 are positioned in a layer above the encapsulation material such that the phosphor particles are remotely distributed from the LED chip. The layer of phosphor particles 106 may be a semicircular or hemispherical layer. The layer of phosphor particles 106 may form a luminescent element above LED chip 102. In some embodiments, phosphor particles 106 are applied in a second layer of material 108 after a first layer of material 108 is used to encapsulate LED chip 102 in cup 104. In some embodiments, a different material is used to apply phosphor particles 106 above material 108.

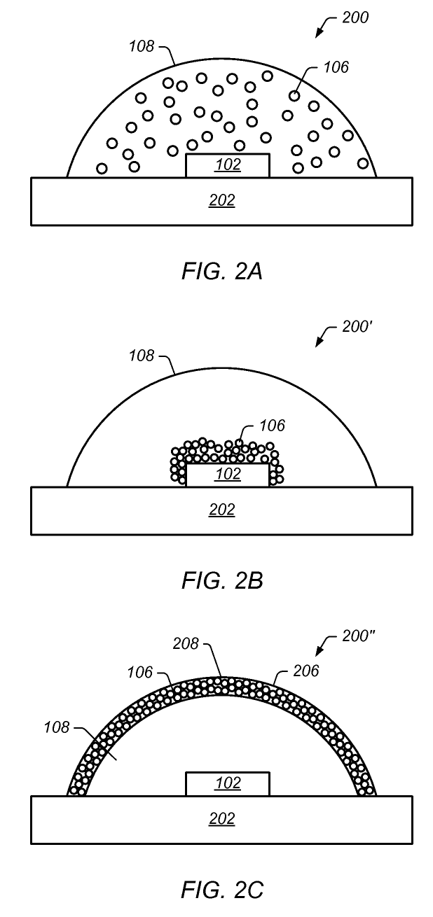

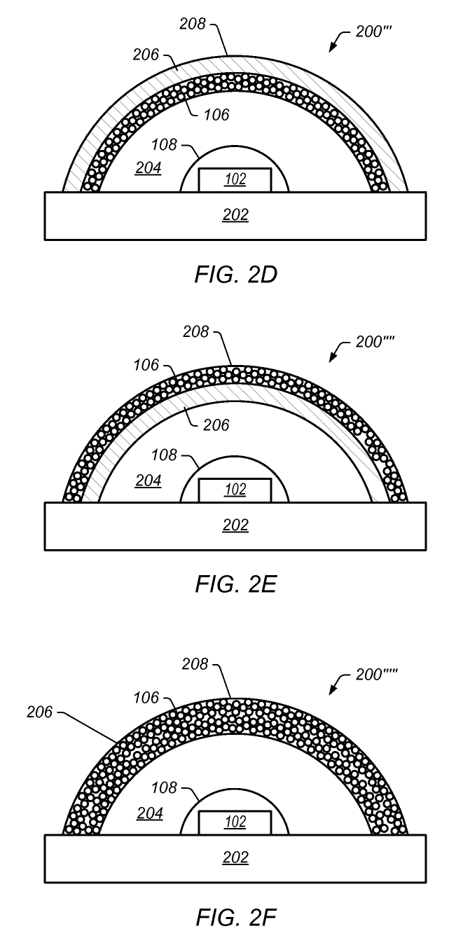

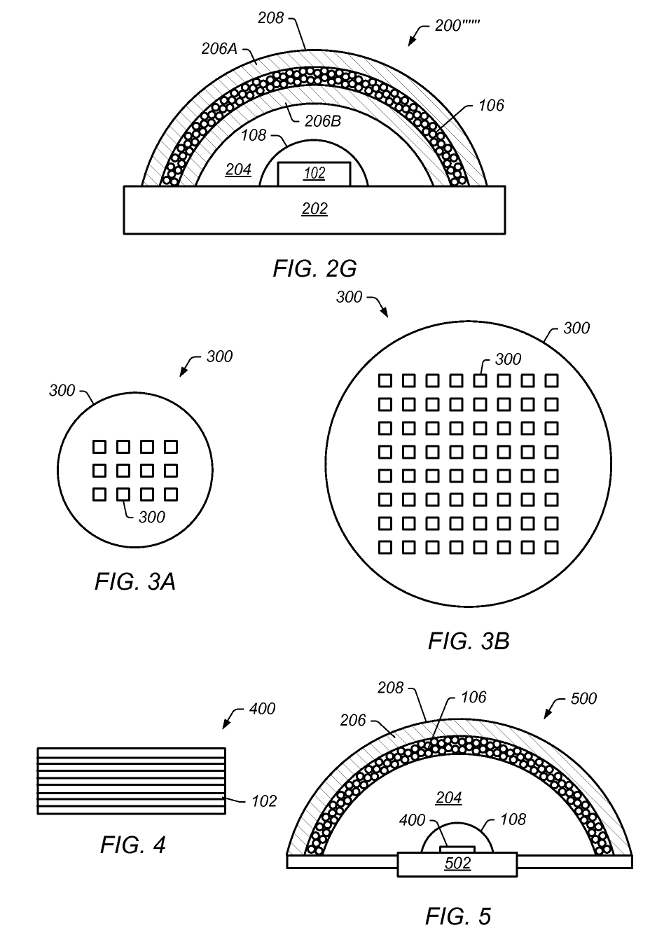

FIGS. 2A-C depict side-view representations of embodiments of an LED chip packaged on a base (e.g., a board or lead frame) with different phosphor distributions. FIG. 2A depicts a side-view representation of an embodiment of LED package 200 with LED chip 102 packaged on base 202 with uniform distribution of phosphor particles 106. FIG. 2B depicts a side-view representation of an embodiment of LED package 200′ with LED chip 102 packaged on base 202 with conformal distribution of phosphor particles 106. FIG. 2C depicts a side-view representation of an embodiment of LED package 200″ with LED chip 102 packaged on base 202 with remote distribution of phosphor particles 106.

As shown in FIGS. 2A-C, base 202 may be a board or lead frame. LED chip 102 may be mounted on base 202 using, for example, silver paste. In some embodiments, the adhesive material may be the same material as material 108 used to enclose LED chip 102.

As shown in FIG. 2A, phosphor particles 106 are substantially uniformly distributed in material 108. Material 108 may be formed in a hemispherical shape (for example, as a bead) over LED chip 102 and base 202. In certain embodiments, phosphor particles 106 are mixed with material 108 to provide a substantially uniform distribution of the particles before encapsulating LED chip 102 in material 108. Phosphor particles 106 and material 108 may form a luminescent element above LED chip 102.

As shown in FIG. 2B, phosphor particles 106 have a conformal distribution around the surface of LED chip 102 and the phosphor particles and the LED chip are enclosed in material 108 above base 202. In certain embodiments, phosphor particles 106 are distributed on the surface of LED chip 102 (e.g., positioned on the surface of the LED chip) and then the LED chip and the phosphor particles are encapsulated in material 108. For example, phosphor particles 106 may be coated on LED chip 102 before encapsulation in material 108. Phosphor particles 106 in material 108 may form a luminescent element above LED chip 102.

As shown in FIG. 2C, LED chip 102 is encapsulated in material 108 and cover 206 is positioned above the encapsulating material. In certain embodiments, phosphor particles 106 are positioned (e.g., distributed) in cover 206 to form luminescent element 208 such that the phosphor particles are remotely distributed from LED chip 102. Cover 206 may be semicircular or hemispherical. Thus, the layer of phosphor particles 106 may be in a semicircular or hemispherical layer above LED chip 102. In some embodiments, cover 206 is the same material as material 108. In some embodiments, cover 206 is a different material than material 108. For example, cover 206 may include polymer and/or ceramic material such as, but not limited to, silicone, epoxy, acrylic, and/or glass.

FIGS. 2D-G depict side-view representations of alternate embodiments of LED packages with LED chip 102 packaged on base 202 with remote distribution of phosphor particles 106. As shown in FIGS. 2D-G, LED packages 200′″, 200″″, 200′″″, 200″″″ include LED chip 102 encapsulated in material 108 on base 202. In certain embodiments, cover 206 is positioned above the encapsulating material. Cover 206 may be semicircular or hemispherical. Cover 206 may be spaced from LED chip 102. In certain embodiments, cover 206 is positioned with air gap 204 between material 108 and the cover. Cover 206 may include polymer and/or ceramic material such as, but not limited to, silicone, epoxy, acrylic, and/or glass.

In certain embodiments, phosphor particles 106 are located in a layer on an inside surface or an outside surface of cover 206 to form luminescent element 208. As shown in FIG. 2D, luminescent element 208 in LED package 200′″ includes phosphor particles 106 located in a layer on the inside surface of cover 206 (e.g., the phosphor particles are coated on the inside surface of the cover). Thus, LED package 200′″ includes LED chip 102 encapsulated in material 108 on base 202 with air gap 204 positioned between the layer of phosphor particles 106 and material 108. As shown in FIG. 2E, luminescent element 208 in LED package 200″″ includes phosphor particles 106 located in a layer on the outside surface of cover 206 (e.g., the phosphor particles are coated on the outside surface of the cover). Thus, LED package 200″″ includes LED chip 102 encapsulated in material 108 on base 202 with air gap 204 positioned between cover 206 and material 108.

In certain embodiments, phosphor particles 106 are contained within cover 206. For example, as shown in FIG. 2F, luminescent element 208 in LED package 200′″″ includes phosphor particles 106 contained within cover 206. Luminescent element 208 may be formed from a mixture of phosphor particles and material used to form cover 206 (e.g., polymer). For example, the polymer and the phosphor may be combined into a mixture and then shaped into cover 206 to form luminescent element 208 (e.g., the cover with contained phosphor particles 106).

In the embodiment of LED package 200″″″ depicted in FIG. 2G, luminescent element 208 includes phosphor particles 106 positioned in a layer between outer cover 206A and inner cover 206B. Outer cover 206A may be, for example, a cover that acts as a heat sink. Inner cover 206B may be a cover used as a tuner cap (e.g., the inner cover tunes the wavelength of light passing through the inner cover and out of the LED package).

In certain embodiments, the size of an LED array inside an LED package is increased by increasing the number of LED chips inside the LED package. For example, a plurality of LED chips may form an LED array (by being electrically connected in series and/or in parallel) and be located inside either an embodiment of LED package 100 (shown in FIGS. 1A-C) or an embodiment of LED package 200 (shown in FIGS. 2A-G). FIG. 3A depicts a top view of an embodiment of LED array 300 with a plurality of LED chips 102 located inside LED package 302. LED package 302 may be similar to any of the embodiments of LED package 100 or LED package 200 described herein. LED chips 102 may be individually encapsulated or encapsulated as groups of LED chips inside LED package 302. As shown in FIG. 3A, twelve (12) LED chips 102 are located inside LED package 302.

FIG. 3B depicts a top view of an embodiment of LED array 300′, which is larger than LED array 300. LED array 300′, as shown in FIG. 3B, includes sixty-four (64) LED chips 102. Increasing the number of LED chips 102 (e.g., increasing the size of the LED array from LED array 300 to LED array 300′) increases the total light output from the LED array.

In embodiments of LED package 302 with uniform phosphor particle distribution (e.g., similar to the embodiments of LED packages 100 and 200 depicted in FIGS. 1A and 2A, respectively) or conformal phosphor particle distribution (e.g., similar to the embodiments of LED packages 100′ and 200′ depicted in FIGS. 1B and 2B, respectively), however, increasing the size of the LED array also increases the amount of phosphor particles (e.g., phosphor particles 106) and/or the amount of encapsulating material (e.g., material 108) used in the LED package. Increasing the amounts of phosphor particles and/or encapsulating material may increase the cost for making LED package 302. Additionally, increasing the size of the LED array may increase other costs related to other components used in combination with the LED array. For example, costs related to a sub frame for the LED array, a metal core printed circuit board (MCPCB) for the LED array, silver paste, and/or wire may also be increased.

In embodiments of LED package 302 with remote phosphor particle distribution (e.g., similar to the embodiments of LED packages 100″ (depicted in FIG. 1C) and LED packages 200″-200″″″ (depicted in FIGS. 2C-G)), increasing the size of the LED array also increases the amount of phosphor particles and/or the amount of encapsulating material used in the LED package. Additionally, increasing the size of the LED array may increase other costs related to other components used in combination with the LED array such as, but not limited to, a sub frame for the LED array, a metal core printed circuit board (MCPCB) for the LED array, silver paste, and/or wire.

Using remote phosphor particle distribution does, however, provide some advantages over using uniform or conformal phosphor particle distributions. For example, remote phosphor particle distribution may provide thermal advantages such as reducing heat in LED chip 102 and/or reducing heat in phosphor particles 106. Reducing the heat in LED chip 102 and/or in phosphor particles 106 may increase the lifetime of the LED chip and/or the phosphor particles, improve reliability of the LED array, and improve performance of the LED array. Using remote phosphor particle distribution may, however, provide an even more dramatic increase in the amount of phosphor particles used relative to using uniform or conformal distribution as the size of the phosphor particle layer is much more dramatically increased for remote distribution because of the comparatively larger size of the phosphor layer in the remote distribution embodiments. For example, doubling the radius of the LED array may quadruple the surface area of the phosphor particle layer for the remote distribution embodiments.

To overcome some of the problems associated with making large LED arrays such as LED array 300′ shown in FIG. 3B, LED chips 102 may be vertically stacked. FIG. 4 depicts a side-view representation of LED unit 400 with vertically stacked epitaxial structures 102′. In some embodiments, LED unit 400 is an LED array (e.g., the epitaxial structures in the LED unit are coupled to form the LED array). As shown in FIG. 4, LED unit 400 includes nine (9)

vertically stacked epitaxial structures 102′. It is to be understood that the number of vertically stacked epitaxial structures may vary depending on, for example, a desired light output of LED unit 400 or manufacturing limitations.

LED unit 400 may be formed by vertically stacking epitaxial structures 102′ using various stacking processes. In some embodiments, epitaxial structures 102′ are vertically stacked using an epitaxial process. For example, LED unit 400 may be formed by epitaxially growing layers for each successive epitaxial structure 102′ on top of each other to form the LED unit. In certain embodiments using the epitaxial process, a tunnel junction is formed between the bottom epitaxial structure and the top epitaxial structure (and/or between other epitaxial structures in the LED unit). The tunnel junction may be highly doped or polarization induced (either single film or multiplayer).

In some embodiments, epitaxial structures 102′ are vertically stacked using a chip process. For example, LED unit 400 may be formed by bonding (coupling) individual epitaxial structures 102′ together into a vertical stack to form the LED unit. In some embodiments, epitaxial structures 102′ are coupled to each other with a bonding layer between the epitaxial structures. In some embodiments, the bonding layer is an adhesive layer, an oxide layer, and/or a metal layer.

Vertically stacking epitaxial structures 102′ using either the epitaxial process or the chip process produces a vertical stack of epitaxial structures without any intervening substrate between the epitaxial structures. Having no intervening substrate between the epitaxial structures minimizes the height of LED unit 400 and simplifies connectability and/or operation of the LED unit.

In certain embodiments, epitaxial structures 102′ in LED unit 400 emit substantially the same wavelength of light. In some embodiments, epitaxial structures 102′ in LED unit 400 emit different wavelengths of light. For example, lower epitaxial structures in the LED unit may emit light with longer wavelengths than upper epitaxial structures. In some embodiments, epitaxial structures 102′ in LED unit 400 are connected in series to form an LED array. In some embodiments, epitaxial structures 102′ in LED unit 400 are connected in parallel to form an LED array. In some embodiments, epitaxial structures 102′ in LED unit 400 are connected in a combination of series and parallel to form an LED array.

After forming LED unit 400 using the epitaxial process or the chip process, the LED unit may be positioned in an LED package with phosphor particles (e.g., a luminescent element) using any of the techniques described herein. In certain embodiments, LED unit 400 is positioned in an LED package with a remote distribution of phosphor particles (e.g., the luminescent element is spaced from the LED unit). FIG. 5 depicts a side-view representation of an embodiment of LED unit 400 positioned in LED package 500. LED package 500 may be similar to LED package 200″ (shown in FIG. 2D).

In certain embodiments, LED package 500 includes LED unit 400 coupled to (mounted on) base 502. LED unit 400 may be enclosed (encapsulated) in material 108. Material 108 may have a hemispherical shape above LED unit 400 (e.g., shape of a bead of material on base 502). Luminescent element 208 in LED package 500 includes phosphor particles 106 located in a layer on the inside surface of cover 206 (e.g., the phosphor particles are coated on the inside surface of the cover). Thus, LED package 500 includes LED unit 400 encapsulated in material 108 on base 502 with air gap 204 positioned between the layer of phosphor particles 106 and material 108.

In certain embodiments, LED package 500 with vertically stacked epitaxial structures 102′ in LED unit 400 uses substantially similar amounts of encapsulating material and/or phosphor particles as LED packages with only one LED chip (e.g., LED package 200′ shown in FIG. 2D). Vertically stacking epitaxial structures 102′ in LED unit 400 may significantly reduce the amount of encapsulating material and/or phosphor particles needed in LED package 500 as compared to an LED array using laterally spaced LED chips (e.g., LED arrays 300 and 300′ shown in FIGS. 3A and 3B, respectively).

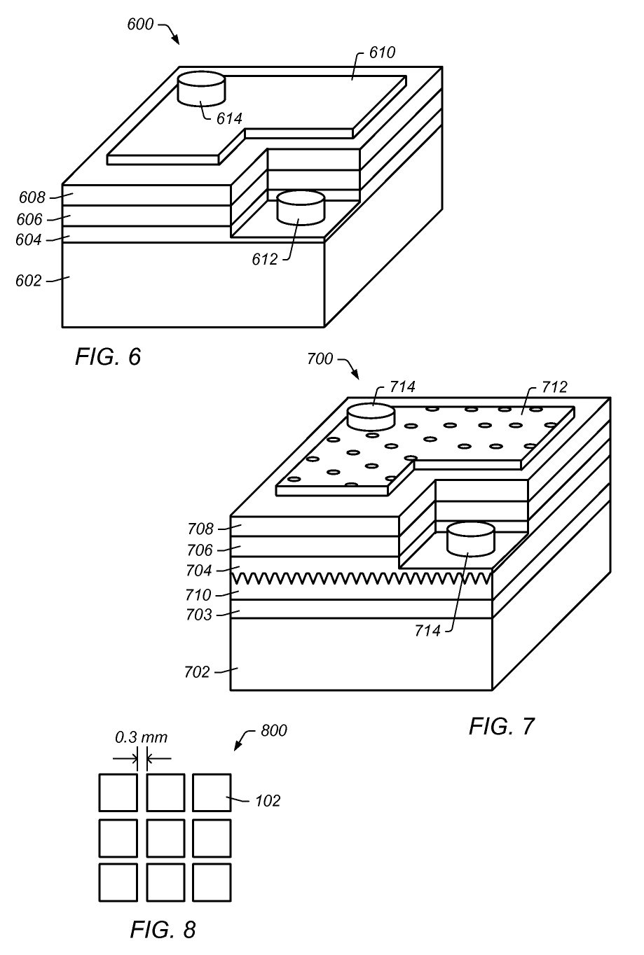

FIG. 6 depicts a representation of an embodiment of sapphire based LED chip 600. LED chip 600, or a portion of the LED chip, may be used as epitaxial structure 102′ described herein (e.g., epitaxially formed layers such as n-doped layer 604, light emitting layer 606, and p-doped layer 608). In certain embodiments, LED chip 600 includes sapphire substrate 602. In certain embodiments, LED chip 600 is a GaN based LED chip. N-doped layer 604, light emitting layer 606, and p-doped layer 608 may be formed (e.g., epitaxially formed) on substrate 602. Light emitting layer 606 may be a single quantum well (SQW) layer or a multiple quantum well (MQW) layer. In some embodiments, conductive layer 610 (e.g., an ITO (indium tin oxide) layer) is formed over p-doped layer 608. N-electrode 612 may be coupled to n-doped layer 604 and p-electrode 614 may be coupled to p-doped layer 608 through conductive layer 610.

FIG. 7 depicts a representation of an embodiment of p-side up LED chip 700. LED chip 700, or a portion of the LED chip, may be used as epitaxial structure 102′ described herein (e.g., the p-side up LED chip may be used in LED unit 400, shown in FIG. 4). In certain embodiments, LED chip 700 includes silicon substrate 702. In some embodiments, substrate 702 includes reflective layer 703. In certain embodiments, LED chip 700 is a GaN based LED chip. N-doped layer 704, light emitting layer 706, and p-doped layer 708 may be formed (e.g., epitaxially formed) on a temporary substrate and then transferred and bonded to substrate 702 using adhesive layer 710. Light emitting layer 706 may be a single quantum well (SQW) layer or a multiple quantum well (MQW) layer. In some embodiments, conductive layer 712 (e.g., an ITO (indium tin oxide) layer) is formed over p-doped layer 708. N-electrode 714 may be coupled to n-doped layer 704 and p-electrode 716 may be coupled to p-doped layer 708 through conductive layer 712.

The embodiments of LED chip 600 and LED chip 700 shown in FIGS. 6 and 7, respectively, are not depicted proportionally to scale (horizontally to vertically). In typical embodiments of LED chip 600 and/or LED chip 700, the lateral size (e.g., plan dimension such as length or width) of the LED chip is at least a few orders of magnitude larger than the height of the LED chip (e.g., the height of the epitaxial layers). For example, the lateral size of the LED chip is typically on a scale of millimeters (mm) while the height of the LED chip is on a scale of micrometers (μm).

To provide further example, the length and width of LED chip 600, as shown in FIG. 6, may both be about 45 mil (about 1.143 mm) (e.g., LED chip is a 1.143 mm by 1.143 mm square) while substrate 602 is about 100 μm in height and the epitaxial layers (n-doped layer 604, light emitting layer 606, and p-doped layer 608) are about 6 μm in height. Similarly, the length and width of LED chip 700, as shown in FIG. 7, may both be about 45 mil (about 1.143 mm) (e.g., LED chip is a 1.143 mm by 1.143 mm square) while substrate 702 (including reflective layer 703) is about 100 μm in height, the epitaxial layers (n-doped layer 704, light emitting layer 706, and p-doped layer 708) are about 6 μm in height, and adhesive layer is about 1 μm to about 3 μm in height.

Because the epitaxial structure has a lateral dimension that is at least a few orders of magnitude more than the height of the epitaxial structure, changes in height to produce LED units are more negligible than changes in the lateral dimensions. FIG. 4 depicts an embodiment of LED unit 400 with changes in height to form the LED unit (e.g., vertically stacking the epitaxial structures to form an LED array). FIG. 8 depicts an embodiment of LED array 800 with LED chips 102 spaced laterally to form the LED array. Both LED unit 400 and LED array 800 are shown with nine (9) epitaxial structures 102′ and nine LED chips 102. LED array 800 has nine LED chips 102 with a distance of 0.3 mm between the LED chips.

As shown in FIG. 8, the lateral size of LED array 800 is the lateral size of three (3) LED chips 102 and two distances between the LED chips. Thus, using an embodiment of LED chip that is a 1.143 mm by 1.143 mm square, the lateral size of LED array 800 is (1.143 mm*3+0.3 mm*2) or 4.029 mm. The height of LED array 800 remains at about 6 μm (the height of the epitaxial layers) plus the height of the base (e.g., about 100 μm). Because of the large increase in lateral size of LED array 800 versus a single LED chip, the amount of encapsulating material and/or phosphor particles is increased proportionally or non-proportionally using the laterally spaced LED chips.

As shown in FIG. 4, the lateral size of LED unit 400 is the same as the lateral size of a single LED chip 102. The height of LED unit 400 is nine (9) times the height of the epitaxial layers (e.g., 9*6 μm=54 μm) plus the height of the base (e.g., about 100 μm). Thus, the height of LED unit 400 remains orders of magnitude less than the lateral size of the LED array and the amount of encapsulating material and/or phosphor particles needed for the LED package remains relatively unchanged from the amount of encapsulating material and/or phosphor particles used with a single LED chip.

As shown in FIGS. 4 and 5, vertically stacking epitaxial structures 102′ in LED unit 400 and placing the LED unit in LED package 500 may increase the total light output versus using a single LED chip while relatively unchanging the amount of encapsulating material and/or phosphor particles used in the LED package (e.g., the size of the luminescent element is about relatively unchanged). Using less amounts of encapsulating material and/or phosphor particles may reduce manufacturing and/or product costs associated with making LED package 500.

In addition, LED unit 400 may operate as a point source of light while LED array 800, shown in FIG. 8, operates as a spread out extended/area light source. Typically, the point source of light (LED unit 400) emits light at greater efficiency (e.g., more concentrated) than the spread out extended/area light source (LED array 800). Thus, LED package 500 with LED unit 400 may provide greater optical efficiency than an LED package with LED array 800.

In some embodiments, LED unit 400 is packaged in an LED package with a cup (e.g., a reflector cup). For example, LED unit 400 may be packaged in an LED package similar to LED package 100″ depicted in FIG. 1C. The cup may be the base or support for LED unit 400 in such an LED package.

In some embodiments, multiple LED units 400 are laterally spaced in an LED package to provide a higher light output than a single LED unit. The combination of vertically stacked epitaxial structures with an arrangement of laterally spaced LED units may produce higher light outputs than possible in a single vertically stacked LED unit. The LED package with both vertically stacked epitaxial structures and laterally spaced LED units may use higher amounts of encapsulating material and/or phosphor particles than the LED package with a single LED unit of vertically stacked epitaxial structures but such an LED package may provide much higher light outputs while maintaining many of the advantages of the vertically stacked epitaxial structure unit.

In some embodiments, the plurality of LED units 400 is connected in series to form the LED array. In some embodiments, the plurality of LED units 400 is connected in parallel to form the LED array. In some embodiments, the plurality of LED units 400 is connected in a combination of series and parallel to form the LED array. For example, each LED array may have vertically stacked epitaxial structures connected in series while the LED units are connected in parallel.

In some embodiments, the LED units are interconnected in series and/or in parallel to form the LED array on a single chip. In some embodiments, one LED unit is formed on the single chip and electrically connected in series and/or in parallel with one or more additional LED units to form the LED array. In some embodiments, some LED units are interconnected in series and/or in parallel to form the LED array on the single chip, and the LED array is then electrically connected to one or more additional LED arrays to form a larger LED array.

It is to be understood the invention is not limited to particular systems described which may, of course, vary. It is also to be understood that the terminology used herein is for the purpose of describing particular embodiments only, and is not intended to be limiting. As used in this specification, the singular forms “a”, “an” and “the” include plural referents unless the content clearly indicates otherwise. Thus, for example, reference to “a device” includes a combination of two or more devices and reference to “a material” includes mixtures of materials.

Further modifications and alternative embodiments of various aspects of the invention will be apparent to those skilled in the art in view of this description. Accordingly, this description is to be construed as illustrative only and is for the purpose of teaching those skilled in the art the general manner of carrying out the invention. It is to be understood that the forms of the invention shown and described herein are to be taken as the presently preferred embodiments. Elements and materials may be substituted for those illustrated and described herein, parts and processes may be reversed, and certain features of the invention may be utilized independently, all as would be apparent to one skilled in the art after having the benefit of this description of the invention. Changes may be made in the elements described herein without departing from the spirit and scope of the invention as described in the following claims.

What is claimed is:

1. A light emitting package, comprising:
a base;
one or more LED units coupled to the base, the LED unit comprising a plurality of vertically stacked epitaxial structures, wherein each epitaxial structure comprises at least a first doped layer, at least a light emitting layer, and at least a second doped layer; and
at least one luminescent element spaced a distance from the one or more LED units.

2. The package of claim 1, wherein the base comprises a board, a lead frame, or a cup.

3. The package of claim 1, wherein the plurality of vertically stacked epitaxial structures are epitaxially formed.

4. The package of claim 1, further comprising a tunnel junction between any two of the plurality of vertically stacked epitaxial structures.

5. The package of claim 1, further comprising a bonding layer between any two of the plurality of vertically stacked epitaxial structures.

6. The package of claim 5, wherein the bonding layer comprises an adhesive layer, an oxide layer, or a metal layer.

7. The package of claim 1, wherein the luminescent element comprises:
a cover over the one or more LED units; and
a phosphor layer contained within the cover or coated on an inside or an outer surface of the cover.

8. The package of claim 7, wherein the cover comprises polymer and/or ceramic.

9. The package of claim 7, further comprising a layer of encapsulating material substantially enclosing the one or more LED units on the base.

10. The package of claim 9, wherein the encapsulating material is substantially transparent to light emitted by the one or more LED units.

11. The package of claim 9, wherein the phosphor layer is separated from the encapsulating material layer by an air gap.

12. The package of claim 1, wherein the LED unit comprises a total light output greater than a total light output from a single epitaxial structure, and wherein the luminescent element is approximately the same size as a luminescent element needed for the single epitaxial structure.

13. The package of claim 1, wherein the light emitting package comprises an LED array formed by interconnecting a plurality of the LED units on a single chip.

14. A method for forming a light emitting package, comprising:
vertically stacking a plurality of epitaxial structures to form an LED unit, wherein each epitaxial structure comprises at least a first doped layer, at least a light emitting layer, and at least a second doped layer;
coupling one or more LED units to a base to form an LED array; and
forming at least one luminescent element above the LED array, wherein the luminescent element is spaced a distance from the LED array.

15. The method of claim 14, wherein the base comprises a board, a lead frame, or a cup.

16. The method of claim 14, further comprising vertically stacking the plurality of epitaxial structures by epitaxially growing layers for each successive epitaxial structure on top of each other.

17. The method of claim 14, further comprising forming a tunnel junction between any two of the plurality of vertically stacked epitaxial structures.

18. The method of claim 14, further comprising bonding any two of the plurality of vertically stacked epitaxial structures to each other using a bonding layer.

19. The method of claim 18, wherein the bonding layer comprises an adhesive layer, an oxide layer, or a metal layer.

20. The method of claim 14, further comprising forming the luminescent element by:
providing a cover;
forming a phosphor layer on an inside or an outer surface of the cover; and
positioning the cover over the LED array, wherein the cover is spaced apart from the LED array.

21. The method of claim 14, further comprising forming the luminescent element by:
providing and mixing at least one polymer and at least one phosphor to form a mixture;
shaping the mixture into a cover; and
positioning the cover over the LED array, wherein the cover is spaced apart from the LED array.

22. The method of claim 21, wherein the polymer comprises silicone, epoxy, or acrylic.

23. The method of claim 14, wherein the luminescent element is approximately the same size as a luminescent element needed for a single epitaxial structure.

24. A light emitting package, comprising:
a base;
one or more LED units coupled to the base, the LED unit comprising a plurality of vertically stacked epitaxial structures, wherein each epitaxial structure comprises at least a first doped layer, at least a light emitting layer, and at least a second doped layer; and
an encapsulating material enclosing the one or more LED units, wherein the LED unit comprises a total light output greater than a total light output from a single epitaxial structure, and wherein the encapsulating material is approximately the same amount as encapsulating material needed for the single epitaxial structure.
